(19) United States
(12) Patent Application Publication
(10) Pub. No.: US 2024/0419875 A1
(43) Pub. Date: Dec. 19, 2024

(54) MODELING ELECTROLYZER OPERATING POINTS

(71) Applicant: Schlumberger Technology Corporation, Sugar Land, TX (US)

(72) Inventors: Anshuman Sarawagi, Calgary (CA); Christopher James Arthur, Calgary (CA); Sogol Mottaghi-Tabar, Calgary (CA)

(21) Appl. No.: 18/743,480

(22) Filed: Jun. 14, 2024

Related U.S. Application Data
(60) Provisional application No. 63/508,586, filed on Jun. 16, 2023.

(51) Int. Cl. G06F 30/28

(52) U.S. Cl. CPC G06F 30/28

(57) ABSTRACT

Methods, systems, and computing systems for operating an electrolyzer include obtaining a ratio of diffusivity in a material at a reference temperature, simulating operation of the electrolyzer in the material at a plurality of current density values at an operating temperature that is different from the reference temperature based at least in part on the ratio of diffusivity, and displaying a result comprising data representing the operation of the electrolyzer using a computer monitor.

### CROSS-REFERENCE TO RELATED APPLICATIONS

This application claims priority to U.S. Provisional Patent Application having Ser. No. 63/508,586, which was filed on Jun. 16, 2023 and is incorporated herein by reference in its entirety.

### BACKGROUND

Commercial operators of electrolyzers use current-voltage (IV) curves to select efficient operating points for electrolyzer systems. The curves differ depending on system behavior, which may be influenced, among other things, by the temperature of the water (or other material) in which they are used. Generally, these curves are either provided by the manufacturer or are determined experimentally for certain temperatures. System behavior may then be interpolated between curves at temperatures representing actual operation; however, such interpolation is not entirely accurate and introduces uncertainty and error. Experimentally-derived curves may obviate such interpolation errors; however, experimental determination is cumbersome and expensive.

Accordingly, operators generally use simulations of their operation, process design, and troubleshooting during operation to select an operating point. Accurate process simulations of an electrolyzer call for empirical data to determine the relationship between operating potential and current density. Operators may assume a relationship based on an educated estimate or keep the value constant and leave the adjustment to operator judgement in the field. This may reduce the predictability of the model, however, as the model may not reflect an accurate representation of real-world operation or its safety parameters.

### SUMMARY

A method for operating an electrolyzer is disclosed. The method includes obtaining a ratio of diffusivity in a material at a reference temperature, simulating operation of the electrolyzer in the material at a plurality of current density values at an operating temperature that is different from the reference temperature based at least in part on the ratio of diffusivity, and displaying a result comprising data representing the operation of the electrolyzer using a computer monitor.

In an example, the method includes obtaining an experimentally-derived curve for current density and voltage, the experimentally-derived curve representing operation of the electrolyzer in the material at an experimental temperature. The simulating operation of the electrolyzer is based at least in part on the experimentally-derived curve.

In an example, the experimental temperature is different from the reference temperature and different from the operating temperature.

In an example, the method includes selecting an operating point for the electrolyzer based at least in part on the simulating operation of the electrolyzer.

In an example, the method includes causing the electrolyzer to operate at the operating point.

In an example, simulating operation of the electrolyzer includes calculating a potential difference generated by the electrolyzer at the plurality of current density values.

In an example, the simulating of the operation of the electrolyzer is independent of a diffusivity of the material at the operating temperature.

In an example, the ratio of diffusivity is a ratio of diffusivity of a proton and a diffusivity of a mobile ion in the material at the reference temperature.

In an example, the method includes generating a plurality of current-voltage (IV) curves based on the simulating operation of the electrolyzer. Each of the IV curves corresponds to a potential difference as a function of current density in the electrolyzer at a different temperature.

A non-transitory, computer-readable medium is disclosed. The medium stores instructions that, when executed by one or more processors of a computing system, cause the computing system to perform operations. The operations include obtaining a ratio of diffusivity in a material at a reference temperature, simulating operation of an electrolyzer in the material at a plurality of current density values at an operating temperature that is different from the reference temperature based at least in part on the ratio of diffusivity, and displaying a result comprising data representing the operation of the electrolyzer using a monitor.

A computing system is also disclosed. The computing system includes one or more processors, and a memory system including one or more non-transitory, computer-readable media storing instructions that, when executed by at least one of the one or more processors, cause the computing system to perform operations. The operations include obtaining an experimentally-derived curve for current density and voltage, the experimentally-derived curve representing operation of an electrolyzer in a material at an experimental temperature, obtaining a ratio of diffusivity in the material at a reference temperature, simulating operation of an electrolyzer in the material at a plurality of current density values at an operating temperature that is different from the reference temperature based at least in part on the ratio of diffusivity and the experimentally-derived curve, and selecting an operating point for the electrolyzer based at least in part on the simulating operation of the electrolyzer.

In an example, the simulating operation comprises calculating a power input for the electrolyzer based on the current density and voltage.

In an example, the operations further include causing the electrolyzer to operate at the operating point in response to selecting the operating point.

It will be appreciated that this summary is intended merely to introduce some aspects of the present methods, systems, and media, which are more fully described and/or claimed below. Accordingly, this summary is not intended to be limiting.

### BRIEF DESCRIPTION OF THE DRAWINGS

The accompanying drawings, which are incorporated in and constitute a part of this specification, illustrate examples of the present teachings and together with the description, serve to explain the principles of the present teachings. In the figures:

FIG. 1 illustrates an example of a system that includes various management components to manage various aspects of a geologic environment, according to an example.

FIG. 2A illustrates an operating current-voltage curve calculated by a simulator and a reference current-voltage curve, according to an example.

FIG. 2B illustrates a baseline operating current-voltage (IV) curve at an experimental temperature and two predicted curves at other temperatures, based on the baseline (middle) curve, showing a poor prediction using another modeling technique, according to an example.

FIG. 3 illustrates IV curves predicted by an example of a method disclosed herein vs. measured current density and operating voltage (points), according to an example.

FIG. 4 illustrates IV curves predicted by an example of a method disclosed herein vs. measured current density and operating voltage (points), according to an example.

FIG. 5 illustrates IV curves predicted by an example of a method disclosed herein vs. measured current density and operating voltage (points), according to an example.

FIG. 6 illustrates a flowchart of a method for operating an electrolyzer, according to an example.

FIG. 7 illustrates a schematic view of a computing system, according to an example.

### DETAILED DESCRIPTION

Reference will now be made in detail to examples, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits, and networks have not been described in detail so as not to unnecessarily obscure aspects of the examples.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular examples and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques, and workflows that are in accordance with some examples. Some operations in the processing procedures, methods, techniques, and workflows disclosed herein may be combined and/or the order of some operations may be changed.

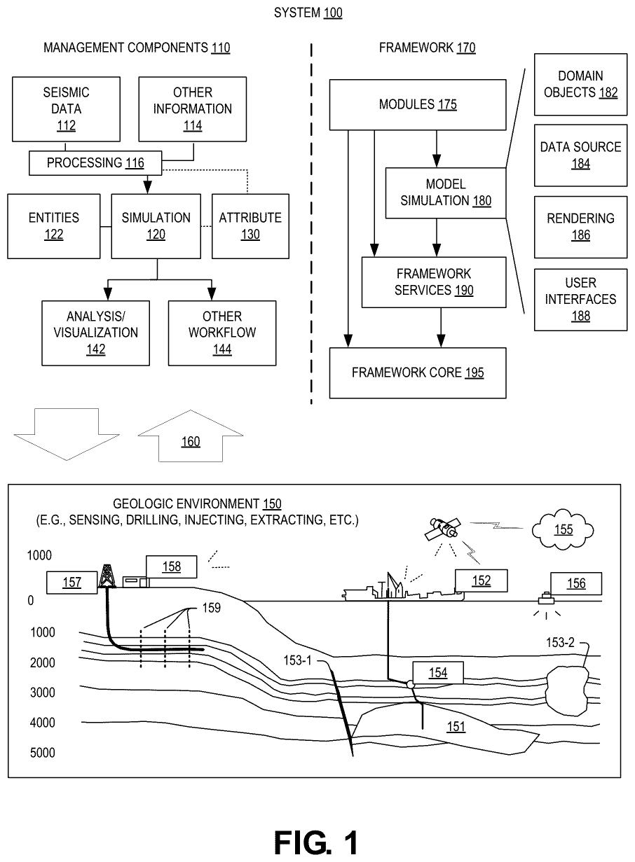

FIG. 1 illustrates an example of a system 100 that includes various management components 110 to manage various aspects of a geologic environment 150 (e.g., an environment that includes a sedimentary basin, a reservoir 151, one or more faults 153-1, one or more geobodies 153-2, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data), a processing component 116, a simulation component 120, an attribute component 130, an analysis/visualization component 142 and a workflow component 144. In operation, seismic data and other information provided per the components 112 and 114 may be input to the simulation component 120.

In an example, the simulation component 120 may rely on entities 122. Entities 122 may include earth entities or geological objects such as wells, surfaces, bodies, reservoirs, etc. In the system 100, the entities 122 can include virtual representations of actual physical entities that are reconstructed for purposes of simulation. The entities 122 may include entities based on data acquired via sensing, observation, etc. (e.g., the seismic data 112 and other information 114). An entity may be characterized by one or more properties (e.g., a geometrical pillar grid entity of an earth model may be characterized by a porosity property). Such properties may represent one or more measurements (e.g., acquired data), calculations, etc.

In an example, the simulation component 120 may operate in conjunction with a software framework such as an object-based framework. In such a framework, entities may include entities based on pre-defined classes to facilitate modeling and simulation. A commercially available example of an object-based framework is the MICROSOFT®.NET® framework (Redmond, Washington), which provides a set of extensible object classes. In the .NET® framework, an object class encapsulates a module of reusable code and associated data structures. Object classes can be used to instantiate object instances for use in by a program, script, etc. For example, borehole classes may define objects for representing boreholes based on well data.

In the example of FIG. 1, the simulation component 120 may process information to conform to one or more attributes specified by the attribute component 130, which may include a library of attributes. Such processing may occur prior to input to the simulation component 120 (e.g., consider the processing component 116). As an example, the simulation component 120 may perform operations on input information based on one or more attributes specified by the attribute component 130. In an example, the simulation component 120 may construct one or more models of the geologic environment 150, which may be relied on to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as the ECLIPSE™ reservoir simulator (Schlumberger Limited, Houston Texas), the INTERSECT™ reservoir simulator (Schlumberger Limited, Houston Texas), etc. As an example, a simulation component, a simulator, etc. may include features to implement one or more meshless techniques (e.g., to solve one or more equations, etc.). As an example, a reservoir or reservoirs may be simulated with respect to one or more enhanced recovery techniques (e.g., consider a thermal process such as SAGD, etc.).

In an example, the management components 110 may include features of a commercially available framework such as the PETREL® seismic to simulation software framework (Schlumberger Limited, Houston, Texas). The PETREL® framework provides components that allow for optimization of exploration and development operations. The PETREL® framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes.

Such a framework may be considered an application and may be considered a data-driven application (e.g., where data is input for purposes of modeling, simulating, etc.).

In an example, various aspects of the management components 110 may include add-ons or plug-ins that operate according to specifications of a framework environment. For example, a commercially available framework environment marketed as the OCEAN® framework environment (Schlumberger Limited, Houston, Texas) allows for integration of add-ons (or plug-ins) into a PETREL® framework workflow. The OCEAN® framework environment leverages. NET® tools (Microsoft Corporation, Redmond, Washington) and offers stable, user-friendly interfaces for efficient development. In an example, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may include the commercially available OCEAN® framework where the model simulation layer 180 is the commercially available PETREL® model-centric software package that hosts OCEAN® framework applications. In an example, the PETREL® software may be considered a data-driven application. The PETREL® software can include a framework for model building and visualization.

As an example, a framework may include features for implementing one or more mesh generation techniques. For example, a framework may include an input component for receipt of information from interpretation of seismic data, one or more attributes based at least in part on seismic data, log data, image data, etc. Such a framework may include a mesh generation component that processes input information, optionally in conjunction with other information, to generate a mesh.

In the example of FIG. 1, the model simulation layer 180 may provide domain objects 182, act as a data source 184, provide for rendering 186 and provide for various user interfaces 188. Rendering 186 may provide a graphical environment in which applications can display their data while the user interfaces 188 may provide a common look and feel for application user interface components.

As an example, the domain objects 182 can include entity objects, property objects and optionally other objects. Entity objects may be used to geometrically represent wells, surfaces, bodies, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results and cases. Thus, upon completion of a modeling session, a user may store a project. At a later time, the project can be accessed and restored using the model simulation layer 180, which can recreate instances of the relevant domain objects.

In the example of FIG. 1, the geologic environment 150 may include layers (e.g., stratification) that include a reservoir 151 and one or more other features such as the fault 153-1, the geobody 153-2, etc. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or instead include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL® software, for example, that operates on seismic data, seismic attribute(s), etc. As an example, a workflow may be a process implementable in the OCEAN® framework. As an example, a workflow may include one or more worksteps that access a module such as a plug-in (e.g., external executable code, etc.).

Examples of the disclosure include systems and methods for operating an electrolyzer. In particular, the electrolyzer may be operated at one of a theoretically infinite number of operating points. That is, they may be operated within a continuous range of potentials, which result in a current across two relatively proximal plates. The result is electrolysis of the “material” (e.g., deionized water, alkaline water, water, carbon dioxide, etc.) between the plates. However, the relationship between the potential difference and the current density is at least partially a function of operating temperature. Accordingly, in at least some examples of the present disclosure, the relationship between potential difference and current density is modeled at a given temperature, e.g., the expected or measured temperature of a system, which may be different from the temperature at which operating data is known (e.g., previously observed and/or provided by manufacturer data). The temperature may be inputted, for example, by an operator. This allows a simulation of an electrolyzer to predict the performance of an electrolyzer unit, in the absence of current density and operating potential data, at the specific operating temperature. The method may be employed in a wide variety of electrolyzer technologies.

Examples of the present disclosure include a simulation that provides a predicted system behavior with a single data set (or potentially a few data sets), rather than receiving current density and potential data for multiple temperatures and interpolating between data sets. Such interpolation generally relies on a linear relationship between the different temperatures which may not be realistic. Further, examples of the present disclosure may not rely on detailed material resistivity information, dimensions of the materials involved, or information about temperature dependence. At least some examples may not call for such comprehensive electrical qualities of the materials, which may not be known to an operating company and may be estimates even for manufacturers.

Additionally, some simulations use empirical or data to tune a set of equations to determine the relationship between amperage, potential and temperature. The present disclosure may not call for empirical data beyond a reference (“experimentally-derived”) current density and operating potential data set. Further, the method may operate outside of the distribution of the available data.

Accordingly, examples of the disclosure may include deriving a mechanistic relationship between the current density, the operating potential, and the steady-state operating temperature of an electrolyzer. Examples of the present disclosure may employ this surprising and unexpected relationship to predict the effect of a temperature, potential or amperage change across different electrolyzer technologies. Further, examples of the present disclosure may provide a predictive process model of an electrolyzer with minimum data requirements to predict performance by creating a more accurate digital twin of commercial electrolyzer units.

The following equations determine the relationship between current density, operating potential, and temperature:

$${V}_{2} = {V}_{th 2} + ( {V}_{1} - {V}_{th 1} ) \qquad ( 1. )$$

$${I}_{2} = {{I}_{1} [ \frac{{T}_{2}}{{T}_{1}} ]}^{[ n ( \frac{{M}_{cathode}}{{M}_{anode}} ) ( \frac{{d}_{proton}}{{d}_{mobile ion}} ) ]} \qquad ( 1.1 )$$

### Where:

### V=Operating Potential [Volts (V)]

### Vₜₕ=Thermodynamic Potential [V]

### I=Current [Amperes (A)]

### T=Temperature [Kelvin (K)]

n=number of electrons exchanged
M=Mole product per mole reactant
d=Diffusivity at 298K
[square meters per second (m²s⁻¹)]

The ratio

$$\frac{{d}_{proton}}{{d}_{mobile ion}}$$

may be determined by the electrolyzer technology and can be estimated from the expected ion transfer. No diffusivity measurement may be called for at the operating temperature (i.e., the simulation equation is “independent of” the diffusivity of the material at the operating temperature); instead, the values may be known at a reference temperature, e.g., 298K. For example, a proton exchange electrolyzer with a H⁺ mobile ion has a ratio of 1 and an alkaline electrolyzer with an OH-mobile ion has a ratio of approximately

$$1.8 ( \frac{{d}_{H +}}{{d}_{O H -}} = \frac{9.31 \times 1 {0}^{- 9} {m}^{2} {s}^{- 1}}{5.27 \times 1 {0}^{- 9} {m}^{2} {s}^{- 1}} = 1.77 ) .$$

Values for diffusivity may be provided empirically or obtained from publicly-available databases.

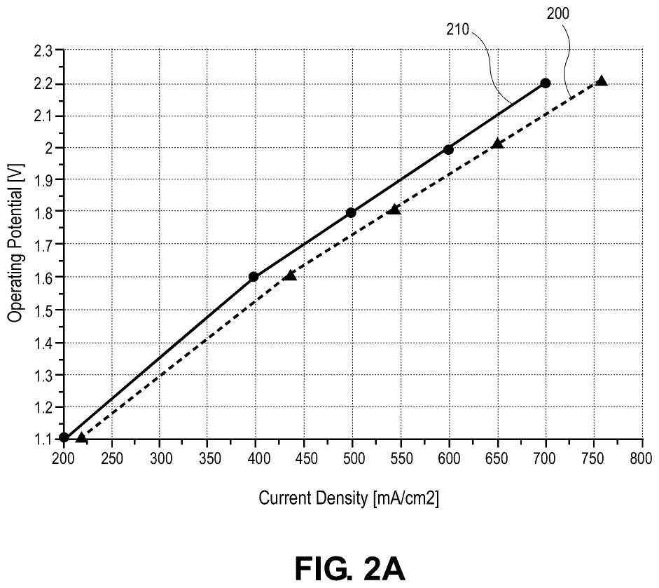

Equations (1.0) and (1.1) allow the simulator to predict the current density, voltage relationship at an alternative temperature to known data. The screenshot of the simulator in FIG. 2A demonstrates the translated current density, voltage relationship at the operating temperature of 830 degree Celsius (° C.) on line 200 compared with the reference relationship at 800° C. on line 210. The simulation can calculate the effect of the temperature increase on the process at the new operating temperature with no additional data.

FIG. 2B shows, for comparison with the results of examples of the current method, the results using other equations to predict electrolyzer behavior at temperatures that have not been tested experimentally. In particular, FIG. 2B illustrates three curves 251, 252, 253. The curve 251 is plotted based on experimentally-derived data points. That is, it is the known case. The other two lines 252, 253 are plotted using the base curve 251 and the Butler-Volmer and Tafel equations to determine the constants relevant to the system. These equations were expected to accurately predict the system behavior. As can be seen in FIG. 2B, however, models based on these equations produce the lines 252, 253 which unexpectedly do not reflect a realistic system, but show large deviations from the experimentally-observed behavior of line 251 with relatively small deviations in temperature and at the ohmic region of the curves which is typically the operating region of an electrolyzer.

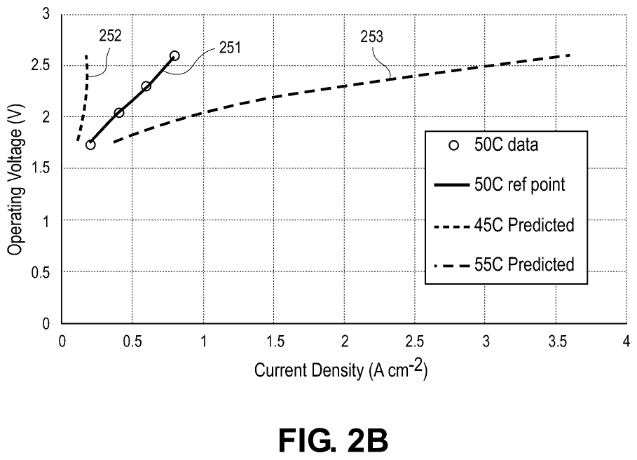

FIGS. 3-5 compare literature data with the output of equations (1.0) and (1.1). In particular, FIG. 3 shows four curves, 301, 302, 303, 304, which represent measured data for a Proton Exchange Membrane at 80° C., 60° C., 40° C., and 30° C. respectively. The points 305 proximal or along each line 301-304 represent calculated results from an example of the present disclosure.

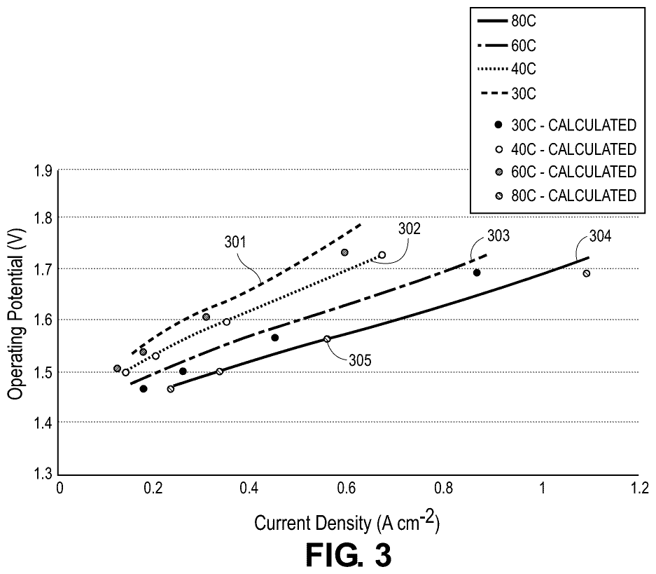

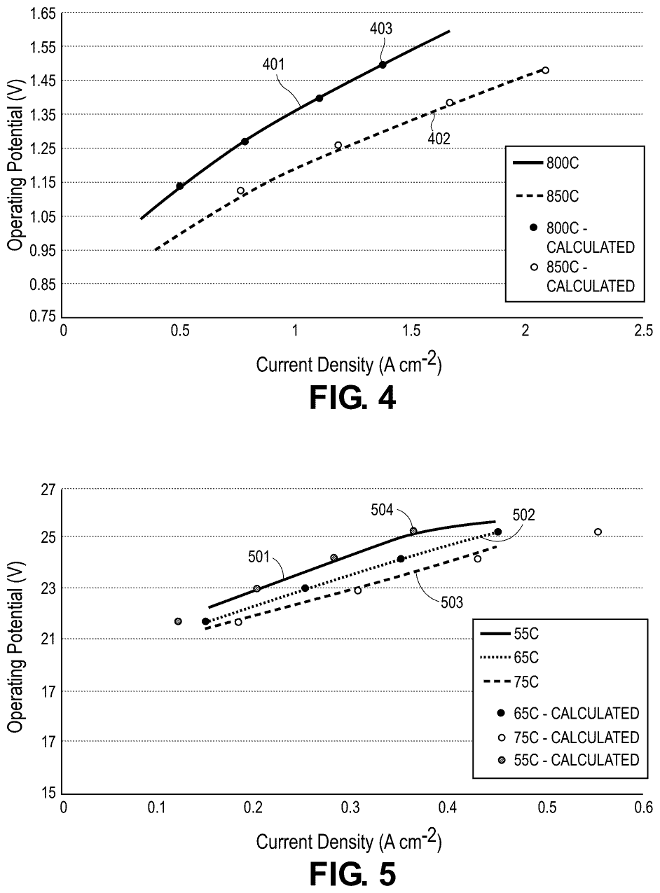

FIG. 4 shows the calculated results points 403 calculated using an example of the present disclosure compared with measured data lines 401, 402 from a solid oxide electrolyzer for carbon dioxide electrolysis at 800° C. and 850° C., respectively. FIG. 5 shows the calculated results (points 504) using an example of the present disclosure compared with measured data (lines 501, 502, 503) from an alkaline water electrolyzer for water electrolysis at 55° C. and 65° C. and 75° C., respectively. It will be appreciated that the present method may be applied to any material suitable for electrolysis and is not limited to any type of water or compound.

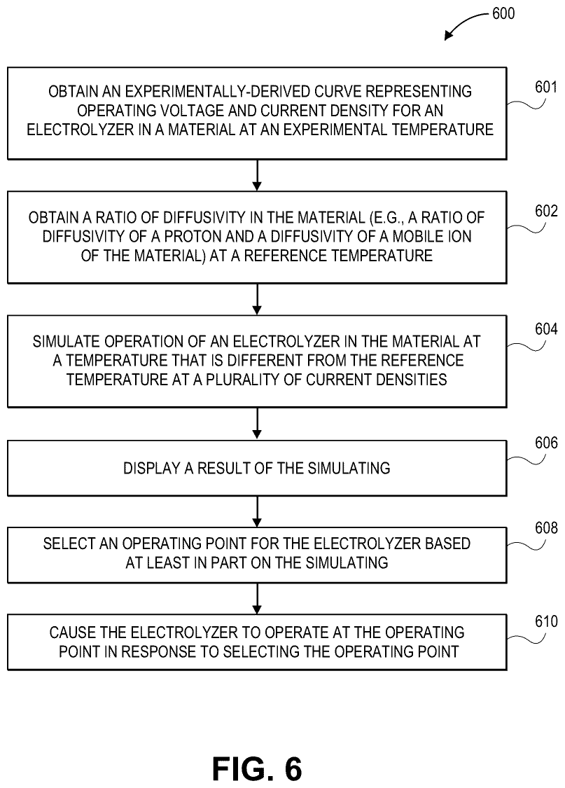

FIG. 6 illustrates a flowchart of a method for operating an electrolyzer, according to an example. The method may include simulating a plurality of operating points for the electrolyzer, e.g., using a simulator such as SYMMETRY®, which is commercially-available from Schlumberger Technology Corporation.

The method 600 may include obtaining at least one (e.g., a single) experimentally-derived IV curve at a particular operating temperature for the electrolyzer in a material (e.g., deionized water, carbon dioxide, alkaline water, any other type of water, etc.), as at 601. The experimentally-derived IV curve may be provided as a relationship (e.g., as a whole curve), or through known operating data points, which were recorded during operation of the electrolyzer in the material at an experimental temperature.

The method 600 may include obtaining a ratio of diffusivity in a material at a reference temperature, as at 602. In at least some examples, the ratio may be between a diffusivity of a proton and a diffusivity of a mobile ion. Further, the reference temperature at which the ratio of diffusivity is provided may be a standard temperature, e.g., 298K. The ratio may be known and provided by prior experimentation at this standard reference temperature, e.g., as recorded in industry literature relevant to the material. The reference temperature may be different from the experimental temperature used to generate the experimentally-derived IV curve.

The method 600 may also include simulating operation of an electrolyzer in the material at an operating temperature that is different from the reference temperature and different from the experimental temperature, and at a plurality of current densities, as at 604. It will be appreciated that the electrolyzer may be referred to as being “in” the material when its plates are at least partially therein so as to provide current through the material. This simulation may employ the equations (1.0) and (1.1) discussed and shown above, among others. Further, this simulation may use the diffusivity ratios obtained at 602 and may permit accurate prediction of system behavior based on the experimentally-derived (“baseline”) curve obtained at 601. Such simulation may permit the calculation of IV curves at the operating temperature, which may be different from the reference temperature and the experimental temperature. As such, the simulation may not call for and may thus be considered independent of the diffusivity of the material at the operating temperature. Further, curves for operation at a plurality of temperatures may be calculated from the simulations.

The method 600 may also include displaying a result of the simulating, as at 606. Such displaying may occur using a computer monitor or any other suitable display. The displayed result may include data representing the simulation, e.g., the curve of potential as a function of current density at the temperature (or temperatures). These results may be more accurate and useful than conventional methods, which, as noted above, may rely on inaccurate interpolation and/or estimated diffusivity properties and/or involve time-intensive experimentation.

The results can be used to select an operating point for the electrolyzer in the material at the operating temperature, as at 608. For example, a human can interpret the curve data of the results and select an amperage for the electrolyzer. In another example, artificial intelligence or rules-based programs may interpret the curve data and select the operating point without including a human user.

In a specific implementation, a user may specify an operating voltage of an electrolyzer. A corresponding current may be calculated using a predefined IV curve. The conversion of, e.g., water to hydrogen and oxygen through operation of the electrolyzer may then be estimated from the current and water flow rates. The electrical power consumed may be calculated from P=IV. Heat loss or gain to maintain the reaction may be calculated via the enthalpy of the products and the feed and environmental heat loss and/or pressure drop. An efficient operating point may be defined where high hydrogen and oxygen are created from an efficient balance of electrical and thermal input. Operational constraints such as water conversion limits, may also be considered in the operating point selection. One of ordinary skill in the art may be capable of selecting the operating point for the electrolyzer, based on accurate IV curves for a selected operating temperature.

Moreover, the IV curves may be a function of temperature among other parameters, such as design and membrane type. Temperature may be a controllable parameter however, and may have a direct effect on the conversion, because it changes the IV curve. The present method permits a user to predict the IV curves at a variety of temperatures based on a single experimentally-derived IV curve. This permits optimization-seeking routines to be run to find an operating temperature for enhanced electrolysis without time-consuming, expensive, and often infeasible experimentation.

The method 600 may also include causing the electrolyzer to operate at the operating point in response to selecting the operating point, as at 610. This may be a manual process, in which a human enters the operating parameters for the electrolyzer. In other examples, causing may include sending a signal to another system that is configured to set the electrolyzer operating point.

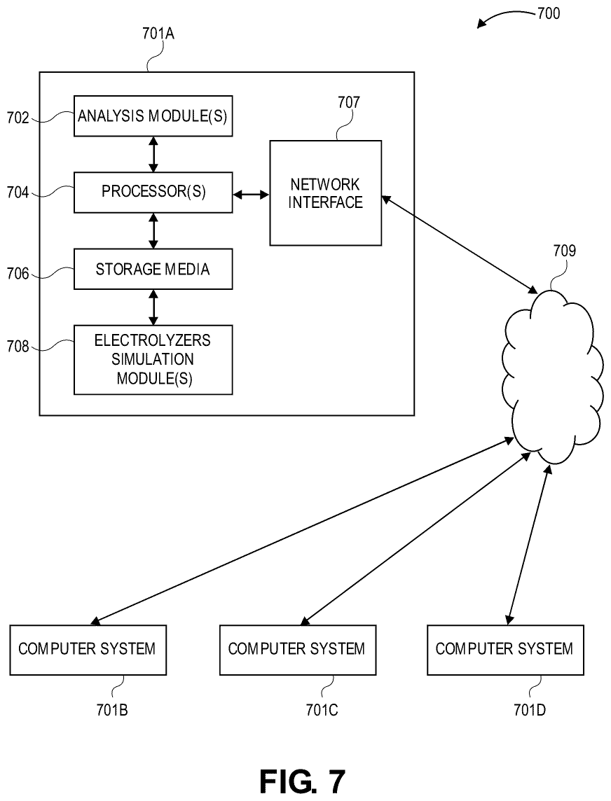

In some examples, the methods of the present disclosure may be executed by a computing system. FIG. 7 illustrates an example of such a computing system 700, in accordance with some examples. The computing system 700 may include a computer or computer system 701A, which may be an individual computer system 701A or an arrangement of distributed computer systems. The computer system 701A includes one or more analysis modules 702 that are configured to perform various tasks according to some examples, such as one or more methods disclosed herein. To perform these various tasks, the analysis module 702 executes independently, or in coordination with, one or more processors 704, which is (or are) connected to one or more storage media 706. The processor(s) 704 is (or are) also connected to a network interface 707 to allow the computer system 701A to communicate over a data network 709 with one or more additional computer systems and/or computing systems, such as 701B, 701C, and/or 701D (note that computer systems 701B, 701C and/or 701D may or may not share the same architecture as computer system 701A, and may be located in different physical locations, e.g., computer systems 701A and 701B may be located in a processing facility, while in communication with one or more computer systems such as 701C and/or 701D that are located in one or more data centers, and/or located in varying countries on different continents).

A processor may include a microprocessor, microcontroller, processor module or subsystem, programmable integrated circuit, programmable gate array, or another control or computing device.

The storage media 706 may be implemented as one or more computer-readable or machine-readable storage media. Note that while in the example of FIG. 7 storage media 706 is depicted as within computer system 701A, in some examples, storage media 706 may be distributed within and/or across multiple internal and/or external enclosures of computing system 701A and/or additional computing systems. Storage media 706 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some examples, computing system 700 contains one or more electrolyzer simulation module(s) 708. In the example of computing system 700, computer system 701A includes the electrolyzer simulation module 708. In some examples, a single electrolyzer simulation module may be used to perform some aspects of one or more examples of the methods disclosed herein. In other examples, a plurality of electrolyzer simulation modules may be used to perform some aspects of methods herein.

It should be appreciated that computing system 700 is merely one example of a computing system, and that computing system 700 may have more or fewer components than shown, may combine additional components not depicted in the example of FIG. 7, and/or computing system 700 may have a different configuration or arrangement of the components depicted in FIG. 7. The various components shown in FIG. 7 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as application-specific integrated chips, field-programmable gate arrays, programmable logic devices, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 700, FIG. 7), and/or through manual control by a user who may make determinations regarding whether a given step, action, template, model, or set of curves has become sufficiently accurate for the evaluation of the subsurface three-dimensional geologic formation under consideration.

The foregoing description, for purpose of explanation, has been described with reference to specific examples. However, the illustrative discussions above are not intended to be exhaustive or limiting to the precise forms disclosed. Many modifications and variations are possible in view of the above teachings. Moreover, the order in which the elements of the methods described herein are illustrate and described may be re-arranged, and/or two or more elements may occur simultaneously. The examples were chosen and described in order to best explain the principles of the disclosure and its practical applications, to thereby enable others skilled in the art to best utilize the disclosed examples and various examples with various modifications as are suited to the particular use contemplated.

What is claimed is:

1. A method for operating an electrolyzer, comprising:
obtaining a ratio of diffusivity in a material at a reference temperature;
simulating operation of the electrolyzer in the material at a plurality of current density values at an operating temperature that is different from the reference temperature based at least in part on the ratio of diffusivity; and
displaying a result comprising data representing the operation of the electrolyzer using a computer monitor.

2. The method of claim 1, further comprising obtaining an experimentally-derived curve for current density and voltage, the experimentally-derived curve representing operation of the electrolyzer in the material at an experimental temperature, wherein the simulating operation of the electrolyzer is based at least in part on the experimentally-derived curve.

3. The method of claim 2, wherein the experimental temperature is different from the reference temperature and different from the operating temperature.

4. The method of claim 1, further comprising selecting an operating point for the electrolyzer based at least in part on the simulating operation of the electrolyzer.

5. The method of claim 4, further comprising causing the electrolyzer to operate at the operating point.

6. The method of claim 1, wherein simulating operation of the electrolyzer includes calculating a potential difference generated by the electrolyzer at the plurality of current density values.

7. The method of claim 1, wherein the simulating of the operation of the electrolyzer is independent of a diffusivity of the material at the operating temperature.

8. The method of claim 1, wherein the ratio of diffusivity is a ratio of diffusivity of a proton and a diffusivity of a mobile ion in the material at the reference temperature.

9. The method of claim 1, further comprising generating a plurality of current-voltage (IV) curves based on the simulating operation of the electrolyzer, wherein each of the IV curves corresponds to a potential difference as a function of current density in the electrolyzer at a different temperature.

10. A non-transitory, computer-readable medium storing instructions that, when executed by one or more processors of a computing system, cause the computing system to perform operations, the operations comprising:
obtaining a ratio of diffusivity in a material at a reference temperature;
simulating operation of an electrolyzer in the material at a plurality of current density values at an operating temperature that is different from the reference temperature based at least in part on the ratio of diffusivity; and
displaying a result comprising data representing the operation of the electrolyzer using a monitor.

11. The medium of claim 10, wherein the operations further comprise obtaining an experimentally-derived curve for current density and voltage, the experimentally-derived curve representing operation of the electrolyzer in the material at an experimental temperature, wherein the simulating operation of the electrolyzer is based at least in part on the experimentally-derived curve.

12. The medium of claim 11, wherein the experimental temperature is different from the reference temperature and different from the operating temperature.

13. The medium of claim 10, wherein the operations further comprise selecting an operating point for the electrolyzer based at least in part on the simulating operation of the electrolyzer.

14. The medium of claim 13, further comprising causing the electrolyzer to operate at the operating point.

15. The medium of claim 10, wherein the simulating operation of the electrolyzer is independent of a diffusivity of the material at the operating temperature.

16. The medium of claim 10, wherein the ratio of diffusivity is a ratio of diffusivity of a proton and a diffusivity of a mobile ion in the material at the reference temperature.

17. The medium of claim 10, wherein the operations further comprise generating a plurality of current-voltage (IV) curves based on the simulating operation of the electrolyzer, wherein each of the IV curves corresponds to a potential difference as a function of current density in the electrolyzer at a different temperature.

18. A computing system, comprising:
one or more processors; and
a memory system comprising one or more non-transitory, computer-readable media storing instructions that, when executed by at least one of the one or more processors, cause the computing system to perform operations, the operations comprising:
obtaining an experimentally-derived curve for current density and voltage, the experimentally-derived curve representing operation of an electrolyzer in a material at an experimental temperature;
obtaining a ratio of diffusivity in the material at a reference temperature;
simulating operation of an electrolyzer in the material at a plurality of current density values at an operating temperature that is different from the reference temperature based at least in part on the ratio of diffusivity and the experimentally-derived curve; and
selecting an operating point for the electrolyzer based at least in part on the simulating operation of the electrolyzer.

19. The computing system of claim 18, wherein the simulating operation comprises calculating a power input for the electrolyzer based on the current density and voltage.

20. The computing system of claim 18, wherein the operations further comprise causing the electrolyzer to operate at the operating point in response to selecting the operating point.
